(19) United States
(12) Patent Application Publication
(10) Pub. No.: US 2015/0076444 A1
(43) Pub. Date: Mar. 19, 2015

(54) SEMICONDUCTOR LIGHT EMITTING ELEMENT AND LIGHT EMITTING DEVICE INCLUDING THE SAME

(71) Applicant: KABUSHIKI KAISHA TOSHIBA, Tokyo (JP)

(72) Inventor: Yuichiro NIIKURA, Nakatsu (JP)

(73) Assignee: KABUSHIKI KAISHA TOSHIBA, Tokyo (JP)

(21) Appl. No.: 14/192,490

(22) Filed: Feb. 27, 2014

(30) Foreign Application Priority Data
Sep. 13, 2013 (JP) 2013-191180

(51) Int. Cl. H01L 33/00; H01L 33/06

(52) U.S. Cl. CPC H01L 33/0033; H01L 33/06; H01L 33/0008
USPC 257/13

(57) ABSTRACT

A semiconductor light emitting element includes a semiconductor substrate including a first region of a first conductivity type. A first semiconductor layer of a second conductivity type is disposed on a first surface of the semiconductor substrate. A second semiconductor layer of the first conductivity type is disposed on the first semiconductor layer with a light emitting layer between the first and second semiconductor layer. A first electrode connects electrically to the first semiconductor layer and a second electrode electrically connects to the second semiconductor layer. A third electrode including a metal is on a second surface of the semiconductor substrate that is opposite the first surface.

### CROSS-REFERENCE TO RELATED APPLICATION

This application is based upon and claims the benefit of priority from Japanese Patent Application No. 2013-191180, filed Sep. 13, 2013, the entire contents of which are incorporated herein by reference.

### FIELD

Embodiments described herein relate generally to a semiconductor light emitting element, and a light emitting device including a semiconductor light emitting element.

### BACKGROUND

A light emitting device is known which includes a semiconductor light emitting element such as a light emitting diode (LED) for a light source, and reduces susceptibility to electrostatic discharges (ESD) by using a protection element such as a Zener diode. This protection element is housed in a package in which the semiconductor light emitting element is also housed, which makes it more difficult to miniaturize the light emitting device, because the available space within the package is decreased. Accordingly, some spatial limitations are imposed on the wiring of a bonding wire which electrically connects the semiconductor light emitting element and the protection element at the time of mounting of the two elements within the same package, for example.

### DESCRIPTION OF THE DRAWINGS

FIGS. 1A and 1B schematically illustrate a semiconductor light emitting element according to an embodiment.

FIGS. 2A through 2D schematically illustrate a light emitting device according to the embodiment.

FIGS. 3A and 3B schematically illustrate another light emitting device according to the embodiment.

FIGS. 4A through 4C are cross-sectional views schematically illustrating a manufacturing process of the semiconductor light emitting element according to the embodiment.

FIGS. 5A through 5C are cross-sectional views schematically illustrating the manufacturing process continuing from FIG. 4C.

FIGS. 6A and 6B are cross-sectional views schematically illustrating a semiconductor light emitting element according to a modified example of the embodiment.

### DETAILED DESCRIPTION

According to one embodiment, a semiconductor light emitting element includes a semiconductor substrate including a first region of a first conductivity type, a first semiconductor layer of a second conductivity type disposed on a first surface of the semiconductor substrate, a second semiconductor layer of the first conductivity type disposed on the first semiconductor layer, a light emitting layer disposed between the first semiconductor layer and the second semiconductor layer, a first electrode electrically connected to the first semiconductor layer, a second electrode electrically connected to the second semiconductor layer, and a third electrode including a metal disposed on a second surface of the semiconductor substrate that is opposite the first surface. A rectifying barrier is formed at a junction between the first region of the semiconductor substrate and the third electrode.

An exemplary embodiment is hereinafter described with reference to the drawings. Similar parts in the respective figures are given similar reference numbers, and the same detailed explanation of these parts is not repeated when not particularly needed. It should be understood that the respective figures are only schematic or conceptual illustrations, and do not necessarily show the relationships between the widths and thicknesses of the respective parts, the ratios of the sizes of the respective parts, and other conditions equivalent to the actual ones. In addition, the sizes and ratios of some parts depicted in one figure may be different from those of the same parts in other figures.

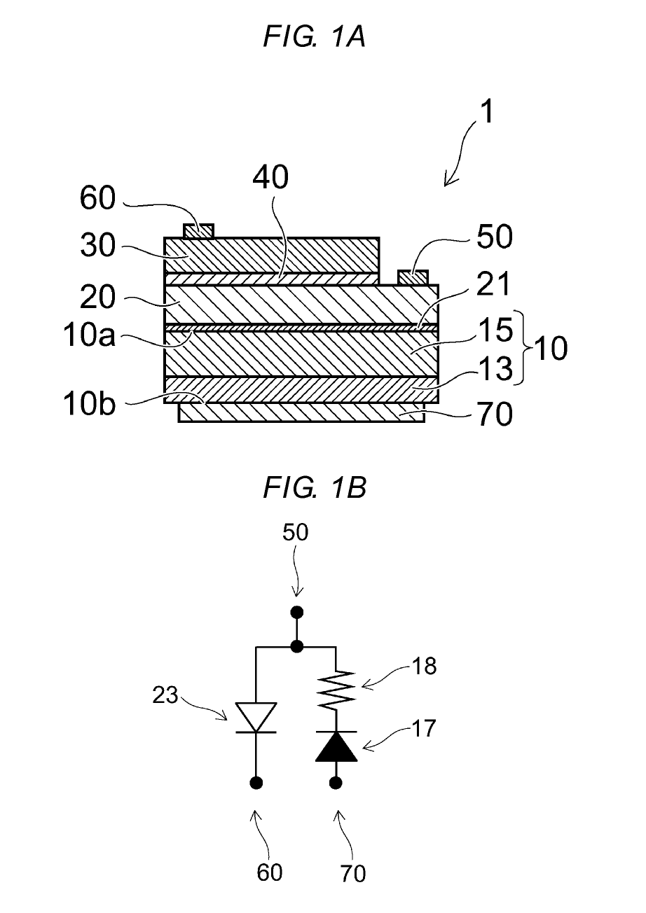

FIGS. 1A and 1B schematically illustrate a semiconductor light emitting element 1 according to this embodiment. FIG. 1A is a cross-sectional view of the semiconductor light emitting element 1, while FIG. 1B shows an equivalent circuit of the semiconductor light emitting element 1.

The semiconductor light emitting element 1 is constituted by an LED, for example, and includes a semiconductor substrate 10, a first semiconductor layer (hereinafter referred to as a p-type semiconductor layer 20) provided on the semiconductor substrate 10, a second semiconductor layer (hereinafter referred to as an n-type semiconductor layer 30) provided on the p-type semiconductor layer 20, and a light emitting layer 40 provided between the p-type semiconductor layer 20 and the n-type semiconductor layer 30.

The semiconductor substrate 10 is a silicon substrate, for example, and includes a first surface 10a and a second surface 10b. The semiconductor substrate 10 is not limited to a silicon substrate, and may be, for example, a conductive substrate and/or comprise other semiconductor material. According to this embodiment, a structure having a p-type conductivity as a first conductivity type and n-type conductivity as a second conductivity type will be discussed as an example; however, the present disclosure is not limited to this, and in other embodiments n-type conductivity may be used as the first conductivity type and p-type conductivity may be used as the second conductivity type.

The semiconductor substrate 10 includes an n-type first area (first region) 13 provided on the second surface 10b side, and a second area (second region) 15 provided on the first surface 10a side. The conductivity type of the second area 15 may be either p-type or n-type. When the conductivity type of the second area 15 is n-type, for example, it is preferable for the n-type impurity concentration of the second area 15 to be higher than the n-type impurity concentration of the first area 13. The n-type impurity concentration of the first area 13 may also be equivalent to the n-type impurity concentration of the second area 15. In this case, there is no requirement to distinguish between the first area 13 and the second area 15.

When the conductivity type of the second area 15 is p-type, the n-type impurity concentration of the first area 13 and the p-type impurity concentration of the second area 15 are determined such that the reverse withstand (breakdown) voltage of a pn junction between the first area 13 and the second area 15 is lower than the reverse withstand voltage of a pn junction between the p-type semiconductor layer 20 and the n-type semiconductor layer 30. For example, the n-type impurity concentration at the contact position (interface) between the first area 13 and the second area 15 may be set at a high concentration.

The p-type semiconductor layer 20 is provided on the semiconductor substrate 10. For example, the p-type semiconductor layer 20 may be formed on the semiconductor substrate 10 by epitaxial growth, or the semiconductor substrate 10 and the p-type semiconductor layer 20 may be joined or bonded to each other. According to this embodiment, the p-type semiconductor layer 20 is joined to the semiconductor substrate 10 via a junction layer 21.

The junction layer 21 includes gold-tin (AuSn) alloy, for example, and electrically connects the semiconductor substrate 10 with the p-type semiconductor layer 20. When the semiconductor substrate 10 absorbs light emitted from the light emitting layer 40, it is preferable that the junction layer 21 contains material reflecting the light emitted from the light emitting layer 40.

The light emitting layer 40 and the n-type semiconductor layer 30 are provided in this order on the p-type semiconductor layer 20. The respective n-type semiconductor layer 30 and the light emitting layer 40 are formed only on a selected part of the p-type semiconductor layer 20. A first electrode (hereinafter referred to as a p-electrode 50) is provided on the exposed surface of the p-type semiconductor layer 20. The p-type electrode 50 is connected with the p-type semiconductor layer 20 by an ohmic connection.

A second electrode (hereinafter referred to as an n-electrode 60) is provided on the n-type semiconductor layer 30. The n-electrode 60 is connected with the n-type semiconductor layer 30 by an ohmic connection. The light emitting layer 40 is caused to emit light by supply of a driving current between the p-electrode 50 and n-electrode 60.

A third electrode (hereinafter referred to as a back electrode 70) is provided on a second surface of the semiconductor substrate 10. A junction having a rectifying property is interposed between the back electrode 70 and the first area 13 of the semiconductor substrate 10. According to this embodiment, the back electrode 70 is connected with the first area 13 by a Schottky connection. In other words, according to the semiconductor light emitting element 1, a Schottky junction having a rectifying property is between the back electrode 70 and the first area 13.

Accordingly, the equivalent circuit of the semiconductor light emitting element 1 includes two diodes, as illustrated in FIG. 1B. One of these diodes is a pn diode 23 between the p-electrode 50 and the n-electrode 60, while the other diode is a Schottky diode 17 between the p-electrode 50 and the back electrode 70. A substrate resistor 18 is interposed between the p-electrode 50 and the Schottky diode 17.

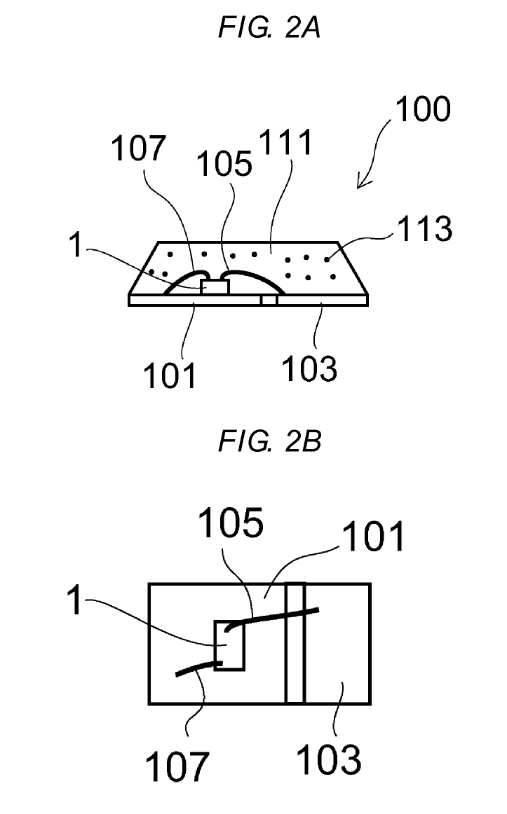

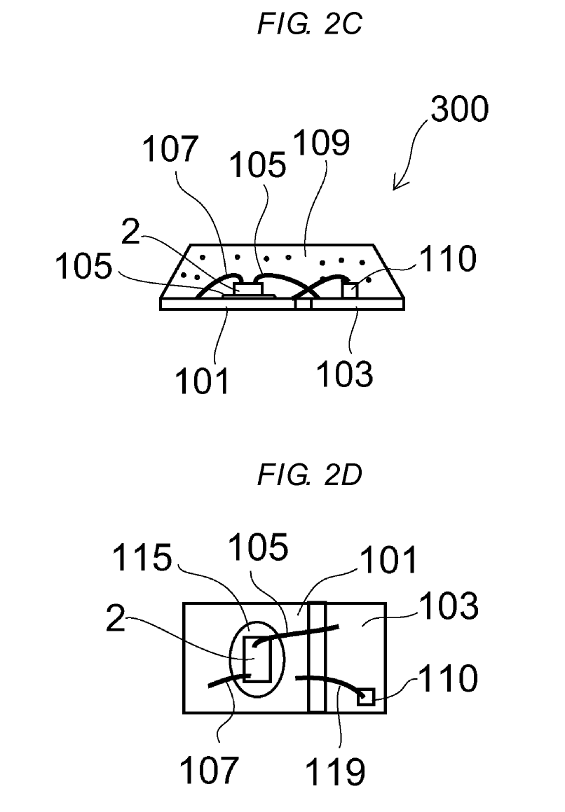

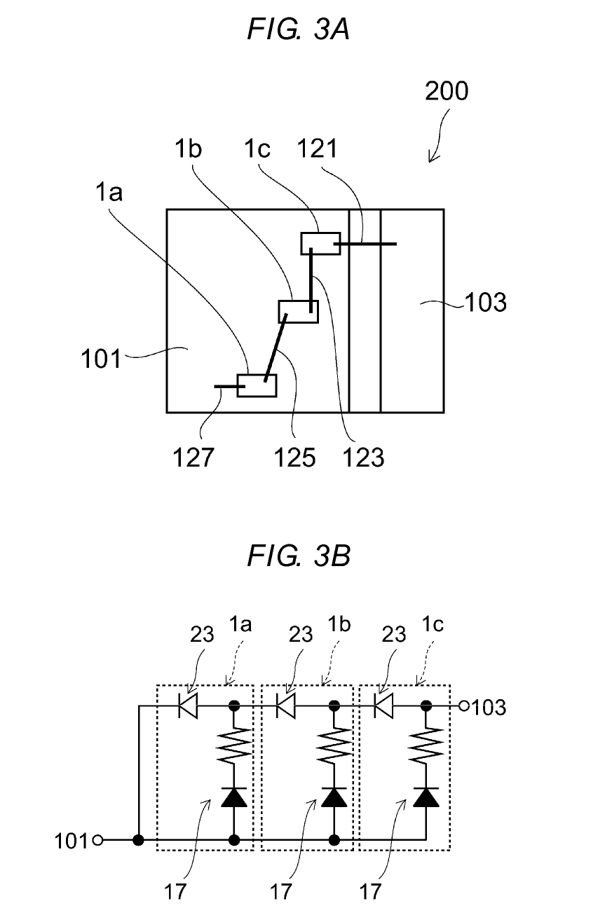

A light emitting device 100 and a light emitting device 200 each of which include a semiconductor light emitting element 1 are described with reference to FIGS. 2A through 2D and FIGS. 3A and 3B.

FIGS. 2A and 2B schematically illustrate the light emitting device 100 according to this embodiment. FIG. 2A is a side view, while FIG. 2B is a top view.

FIGS. 2C and 2D schematically illustrate a light emitting device 300 according to a comparison example. FIG. 2C is a side view, while FIG. 2D is a top view.

As illustrated in FIG. 2A, the light emitting device 100 includes lead frames 101 and 103, the semiconductor light emitting element 1, and a resin 111 sealing the semiconductor light emitting element 1. As illustrated in FIG. 2B, the lead frame 101 and the lead frame 103 are spaced away from each other and arranged in a line. The semiconductor light emitting element 1 is mounted on the lead frame 101. In this case, the semiconductor light emitting element 1 is mounted in such a position that the back electrode 70 faces to the lead frame 101.

For example, the back electrode of the semiconductor light emitting element 1 contains gold (Au), and the surface of the lead frame 101 is gold-plated. According to this structure, the semiconductor light emitting element 1 is connected with the lead frame 101 by a eutectic connection.

The p-electrode 50 provided on the upper surface of the semiconductor light emitting element 1 is electrically connected to the lead frame 103 via a metal wire 105. The n-electrode 60 is electrically connected to the lead frame 101 via a metal wire 107. In this example, the n-electrode 60 and the back electrode 70 are both connected to the lead frame 101, which causes the potentials of the two components 60 and 70 to become electrically equivalent. As a result, the pn diode 23 and the Schottky diode 17 are connected in parallel between the lead frame 101 and the lead frame 103. In this case, the connection direction (e.g., anode-cathode connection) of the pn diode 23 is opposite to the connection direction of the Schottky diode 17 (see FIG. 1B).

According to the light emitting device 100, the light emitting layer 40 is caused to emit light when current is supplied from the lead frame 103 to the lead frame 101 to provide thereby a forward-directional current to the pn diode 23. When the pn diode 23 is reversely biased by, for example, a surge voltage applied between the lead frame 101 and the lead frame 103, a forward-directional current flows in the Schottky diode 17 to thereby prevent a high voltage applied across the pn diode 23. Accordingly, the Schottky diode 17 functions as a protection element for the pn diode 23.

The resin 111 covering the semiconductor light emitting element 1 and the lead frames 101 and 103 includes a fluorescent material 113 which is excited by light emitted from the semiconductor light emitting element 1 and emits light having a wavelength different from the wavelength of the exciting light, for example. Thus, the light emitting device 100 outputs a mixture of light emitted from the semiconductor light emitting element 1, and light emitted from the fluorescent material 113. The color of the outputted light is adjustable by appropriate selection of the type of the fluorescent material 113.

According to the light emitting device 300 shown in FIGS. 2C and 2D, a semiconductor light emitting element 2 is mounted on the lead frame 101. The semiconductor light emitting element 2 does not include the Schottky diode 17 on the back side, but has only the pn diode 23. The light emitting device 300 is equipped with a Zener diode 110 as a protection element.

The p-electrode provided on the upper surface of the semiconductor light emitting element 2 is electrically connected to the lead frame 103 via the metal wire 105. The n-electrode is electrically connected to the lead frame 101 via the metal wire 107. The Zener diode 110 is mounted on the lead frame 101. An electrode provided on the upper surface of the Zener diode is electrically connected to the lead frame 101 by a metal wire 119.

According to the light emitting device 300, a surge voltage applied between the lead frame 101 and the lead frame 103 is absorbed by the Zener diode 110, by which method the pn diode 23 is protected.

According to the light emitting device 300, however, the Zener diode 110 is an additional component to be mounted along with the light emitting device, which causes the total device manufacturing cost to increase. Moreover, the existences of the Zener diode 110 and the metal wire 119 make it difficult to reduce the size of the device. When the number of the semiconductor light emitting elements 2 mounted on the lead frame increases, this disadvantage becomes more apparent and problematic.

However, according to the light emitting device 100 of the present disclosure, the semiconductor light emitting element 1 contains Schottky diode 17 rather than Zener diode 110. Accordingly, the total number of assembly steps decreases, and size reduction of the light emitting device may be more easily achievable.

According to the example shown in FIGS. 2C and 2D, an adhesive such as a conductive paste is applied for mounting the semiconductor light emitting element 2 on the lead frame 101. However, the semiconductor light emitting element 1 is connected to the lead frame 101 by eutectic connection rather via a conductive paste. In this case, the mounting step becomes easier, and the stability of the connection also increases.

FIGS. 3A and 3B schematically illustrate the light emitting device 200 as another example according to the present disclosure. FIG. 3A shows the top surface of the light emitting device 200, while FIG. 3B shows an equivalent circuit included in the light emitting device 200.

As illustrated in FIG. 3A, the light emitting device 200 includes the lead frames 101 and 103, and a plurality of semiconductor light emitting elements 1a through 1c mounted on the lead frame. According to this embodiment, a structure which mounts the three semiconductor light emitting elements 1 will be discussed as an example. However, the number of the semiconductor light emitting elements 1 is not limited to this number but may be four or more, or only two.

For example, the plural semiconductor light emitting elements 1 mounted on the lead frame 101 are connected in series. As illustrated in FIG. 3A, the p-electrode 50 of the semiconductor light emitting element 1c is electrically connected with the lead frame 103 via a metal wire 121. The n-electrode of the semiconductor light emitting element 1c is electrically connected with the p-electrode 50 of the semiconductor light emitting element 1b via a metal wire 123. Similarly, the semiconductor light emitting element 1b is electrically connected with the semiconductor light emitting element 1a via a metal wire 125. The n-electrode 60 of the semiconductor light emitting element 1a is electrically connected with the lead frame 101 via a metal wire 127. The respective back electrodes 70 of the semiconductor light emitting elements 1a through 1c are connected with the lead frame 101 by eutectic connection.

As illustrated in FIG. 3B, the pn diodes 23 of the semiconductor light emitting elements 1a through 1c are connected in series between the lead frame 103 and the lead frame 101. The respective Schottky diodes 17 have anodes in common (connected to each other), and cathodes connected between the lead frame 103 and the pn diode 23, and between the respective pn diodes 23. That is, Schottky diodes 17 each have a respective cathode connected to a connection point between at least one respective pn diode 23 and the lead frame 101.

During operation of the light emitting device 200, a voltage difference between the lead frame 103 and the lead frame 101 is directly applied as a reverse bias to the Schottky diode 17 of the semiconductor light emitting element 1c. According to this structure, the reverse withstand voltage of the Schottky diode 17 puts limitations on the number of the semiconductor light emitting elements 1 to be mounted in series. It is therefore typically preferable to set the reverse withstand voltage of the Schottky diode to a high voltage.

According to the light emitting device 200 on which the plural semiconductor light emitting elements 1 are mounted, the light output from the light emitting device 200 increases. Moreover, the number of the elements and the number of the metal wires provided on the light emitting device 200 are smaller than a structure which uses separately mounted protection elements. Accordingly, the advantages of simplification of the mounting step, and easy miniaturization are both offered.

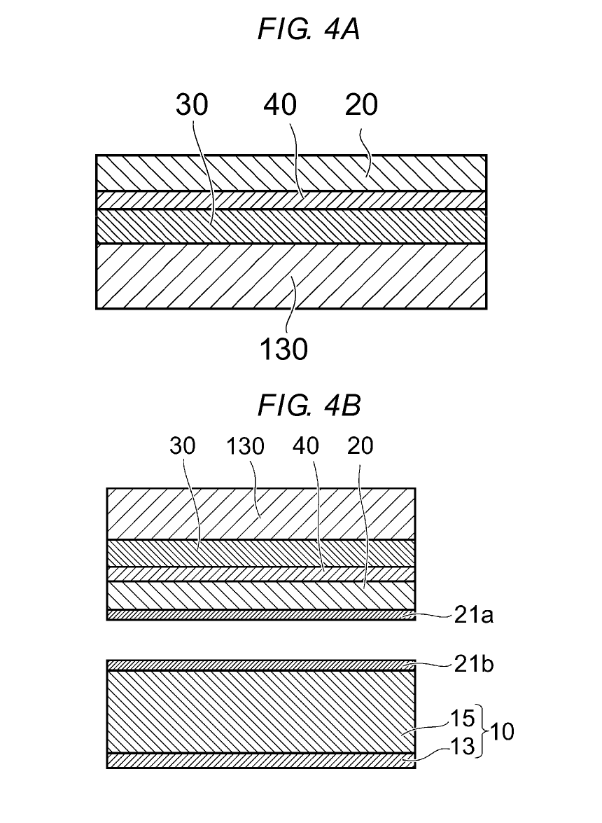

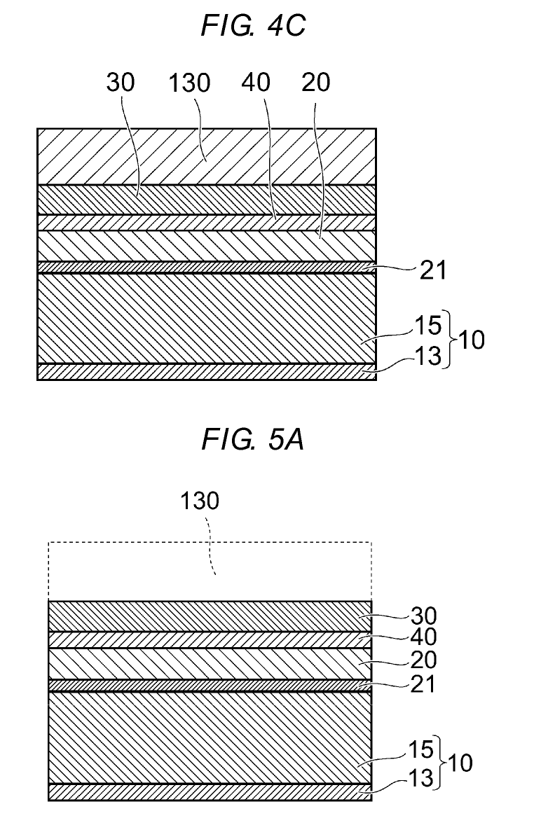

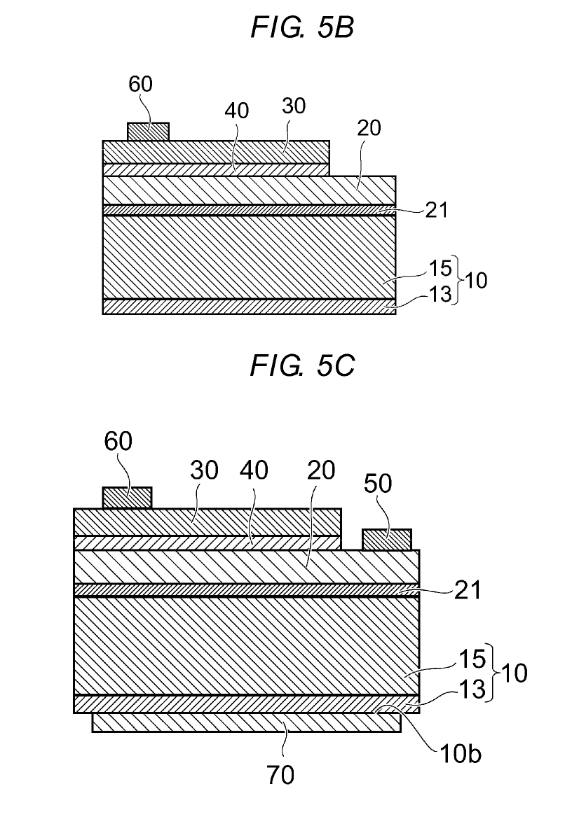

A manufacturing method of the semiconductor light emitting element 1 is now explained with reference to FIGS. 4A through 5C. FIGS. 4A through 5C are cross-sectional views schematically illustrating the manufacturing process of the semiconductor light emitting element 1 according to this embodiment.

As illustrated in FIG. 4A, the n-type semiconductor layer 30, the light emitting layer 40, and the p-type semiconductor layer 20 are formed in this order on a growth substrate 130 formed by a silicon substrate or the like. The layers 30, 40, and 20 can be formed by epitaxial growth, for example. The respective semiconductor layers (30 and 20) and the light emitting layer 40 are constituted by nitride semiconductors, for example, and may be formed by MOCVD (metal organic chemical vapor deposition).

The p-type semiconductor layer 20 and the n-type semiconductor layer 30 are made of gallium nitride (GaN), for example. The light emitting layer 40 has, for example, a multi-quantum well structure containing GaN, InGaN, and emits blue light. A buffer layer (not specifically depicted) may be formed between the growth substrate 130 and the n-type semiconductor layer 30.

After the step in FIG. 4A, the support substrate 10 having the first area 13, the second area 15, and a junction layer 21b provided on the second area 15 is prepared as illustrated in FIG. 4B. On the growth substrate 130 side, a junction layer 21a is formed on the p-type semiconductor layer 20.

After the step in FIG. 4B, the support substrate 10 and the growth substrate 130 are disposed so as to face to each other via the junction layers 21a and 21b, and are joined with each other as illustrated in FIG. 4C. Each of the junction layers 21a and 21b contains a junction material such as AuSn alloy. Then, the support substrate 10 and the growth substrate 130 are pressed and heated from the respective backs of the substrates 10 and 130 to join/bond the substrates 10 and 130.

It is preferable that the junction layer 21a contains a reflective material such as silver (Ag).

After the step in FIG. 4C, the growth substrate 130 is removed as illustrated in FIG. 5A. When the growth substrate 130 is a silicon substrate, selective removal of the growth substrate 130 can be performed by wet etching.

After the step in FIG. 5A, the n-electrode 60 is formed on the n-type semiconductor layer 30 exposed by removal of the growth substrate 130, as illustrated in FIG. 5B. A transparent electrode (not specifically depicted), such as ITO (indium-tin oxide), may be formed on the surface of the n-type semiconductor layer 30.

After the step in FIG. 5B, selective removal of the n-type semiconductor layer 30 and the light emitting layer 40 is carried out to expose a surface of the p-type semiconductor layer 20. For example, an etching mask is formed on the n-type semiconductor layer 30, and selective etching of the n-type semiconductor layer 30 and the light emitting layer 40 is conducted by using RIE (reactive ion etching) for a depth reaching the p-type semiconductor layer 20.

After the step in FIG. 5B, the p-electrode 50 is formed on the exposed part of the p-type semiconductor layer 20 as illustrated in FIG. 5C. The back electrode 70 is also formed on the back (second surface 10b) of the semiconductor substrate (support substrate) 10.

In this embodiment, the p-electrode 50 and n-electrode 60 are formed such that ohmic connections are made to the underlying respective semiconductor layer (layer 20 for p-electrode 50 and layer 30 for n-electrode 60), while the back electrode 70 is formed such that Schottky connection is made to the first area 13. These different connection types are produced by appropriate selection of electrode materials and/or by different settings of heating temperatures, for example.

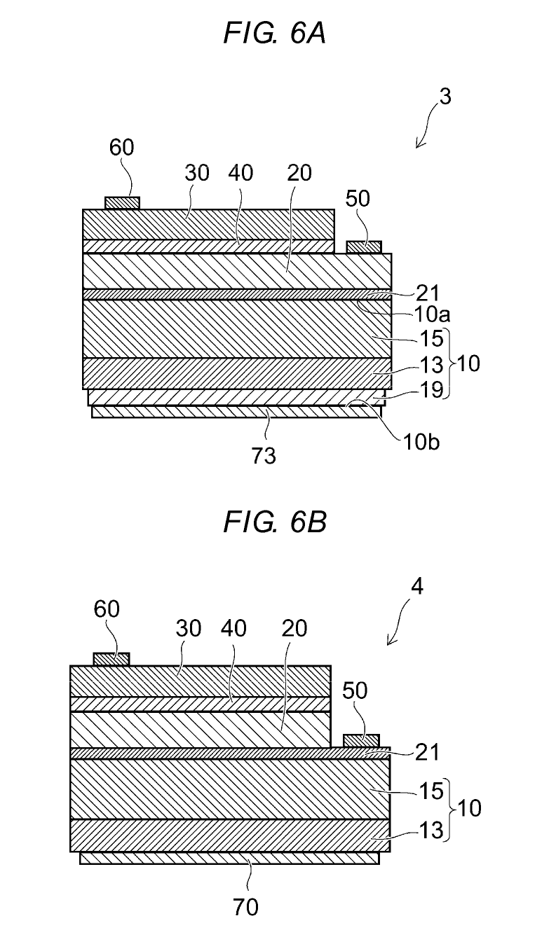

Semiconductor light emitting elements according to modified examples of this embodiment are hereinafter described with reference to FIGS. 6A and 6B. FIGS. 6A and 6B are cross-sectional views schematically illustrating semiconductor light emitting elements 3 and 4 according to the modified examples of the present disclosure.

The semiconductor light emitting element 3 shown in FIG. 6A includes the semiconductor substrate 10, the p-type semiconductor layer 20 provided on the semiconductor substrate 10, the n-type semiconductor layer 30 provided on the p-type semiconductor layer 20, and the light emitting layer 40 provided between the p-type semiconductor layer 20 and the n-type semiconductor layer 30.

The semiconductor substrate 10 includes the second area 15 provided on the first surface 10a side, a p-type third area 19 provided on the second surface 10b side, and the n-type first area 13 provided between the second area 15 and the third area 19.

According to this example, a pn junction is provided between the n-type first area 13 and the p-type third area 19. In addition, a back electrode 73 is provided as a third electrode contacting the third area 19. The back electrode 73 is connected with the third area 19 by an ohmic connection.

It is not required to include the back electrode 73. For example, when the semiconductor substrate 10 is formed by a silicon substrate, the semiconductor light emitting element 3 may be provided on the lead frame and connected therewith by eutectic connection. More specifically, a silicide layer can be formed between the third area 19 and the lead frame, and to connection of these components made via the silicide layer. In this case, the lead frame also functions as the third electrode.

The semiconductor light emitting element 4 shown in FIG. 6B includes the semiconductor substrate 10, the p-type semiconductor layer 20 provided on the semiconductor substrate 10, the n-type semiconductor layer 30 provided on the p-type semiconductor layer 20, and the light emitting layer 40 provided between the p-type semiconductor layer 20 and the n-type semiconductor layer 30.

The semiconductor substrate 10 includes the first area (first region) 13 provided on the second surface 10b side, and the second area (second region) 15 provided on the first surface 10a side. The back electrode 70 is further provided as a component contacting the first area 13. The back electrode 70 is connected with the first area 13 by a Schottky connection.

Furthermore, according to this example, selective etching of the n-type semiconductor layer 30, the light emitting layer 40, and the p-type semiconductor layer 20 is carried out to obtain an exposed surface of the junction layer 21, rather than layer 20 as in semiconductor light emitting element 1. The p-type electrode 50 is formed on the exposed part of the junction layer 21. This structure is useful when etching of the p-type semiconductor layer 20 is difficult to stop upon removal of the n-type semiconductor layer 30 and the light emitting layer 40, for example.

According to the semiconductor light emitting element explained in conjunction with FIGS. 1A through 6B, a junction having a rectifying property is provided on the second surface 10b side of the semiconductor substrate 10. This structure allows formation of a diode functioning as a protection element as an integral part of the light emitting device. Accordingly, the light emitting device provided with the semiconductor light emitting element of this embodiment allows easier mounting of the light emitting element, and constitution of a structure suited for a compact size.

In this specification, it is intended that the “nitride semiconductor” includes a compound semiconductor of III-V family of BₓIn_{y}Al_{z}Ga_{1-x-y-z}N (0≦x≦1, 0≦y≦1, 0≦z≦1, 0≦x+y+z≦1), and further includes mixed crystal containing phosphorus (P), arsenic (As) and others in addition to N (nitrogen) as V family elements. It is further intended that the “nitride semiconductor” includes a semiconductor further containing various elements added to control various physical properties such as conductivity types, and a semiconductor further containing various elements unintentionally included.

While certain embodiments have been described, these embodiments have been presented by way of example only, and are not intended to limit the scope of the present disclosure. Indeed, the novel embodiments described herein may be embodied in a variety of other forms; furthermore, various omissions, substitutions and changes in the form of the embodiments described herein may be made without departing from the spirit of the present disclosure. The accompanying claims and their equivalents are intended to cover such forms or modifications as would fall within the scope and spirit of the present disclosure.

What is claimed is:

1. A light emitting element, comprising:
a semiconductor substrate including a first region of a first conductivity type;
a first semiconductor layer of a second conductivity type disposed on a first surface of the semiconductor substrate;
a second semiconductor layer of the first conductivity type disposed on the first semiconductor layer;
a light emitting layer disposed between the first semiconductor layer and the second semiconductor layer;
a first electrode electrically connected to the first semiconductor layer;
a second electrode electrically connected to the second semiconductor layer; and
a third electrode including a metal disposed on a second surface of the semiconductor substrate that is opposite the first surface.

2. The light emitting element according to claim 1, wherein a Schottky barrier is formed at a junction between the first region and the third electrode.

3. The light emitting element according to claim 1, wherein the semiconductor substrate includes a second region between the first region and the first semiconductor layer, and the second region being the second conductivity type or the first conductivity type of higher impurity concentration than that of the first region.

4. The element according to claim 1, further comprising:
a junction layer disposed between the semiconductor substrate and the first semiconductor layer.

5. The element according to claim 4, wherein the first semiconductor layer is electrically connected to the semiconductor substrate via the junction layer.

6. The element according to claim 4, wherein the junction layer includes a material that reflects light emitted from the light emitting layer.

7. The element according to claim 4, wherein the first electrode is contacting the junction layer.

8. The light emitting element according to claim 1, wherein the semiconductor substrate includes a third region of the second conductivity type between the first region and the third electrode.

9. The light emitting element according to claim 8, wherein a junction between the first region and the third region is a pn junction.

10. A light emitting device, comprising:
a light emitting element including:
a semiconductor substrate including a first region of a first conductivity type;
a first semiconductor layer of a second conductivity type disposed on a first surface of the semiconductor substrate;
a second semiconductor layer of the first conductivity type disposed on the first semiconductor layer;
a light emitting layer disposed between the first semiconductor layer and the second semiconductor layer;
a first electrode electrically connected to the first semiconductor layer;
a second electrode electrically connected to the second semiconductor layer; and
a third electrode including a metal disposed on a second surface of the semiconductor substrate that is opposite the first surface;
a lead frame to which the light emitting element is mounted; and
a resin disposed so as to cover the light emitting element.

11. The light emitting device according to claim 10, wherein the resin includes a fluorescent material that is excited by light emitted from the light emitting element and, upon excitation by the light emitted from the light emitting element, the fluorescent material emits a light having a wavelength that is different from a wavelength of the light emitted from the light emitting element.

12. The light emitting device according to claim 10, wherein a plurality of light emitting elements are mounted to the lead frame.

13. The light emitting device according to claim 12, wherein the plurality of light emitting elements are connected in series with each other.

14. The light emitting device according to claim 10, wherein the light emitting element is mounted to the lead frame by a eutectic connection.

15. The light emitting device according to claim 10, wherein the rectifying barrier between the first region of the light emitting element and the third electrode of the light emitting element is a Schottky barrier.

16. The light emitting device according to claim 10, wherein the light emitting element further includes:
a junction layer disposed between the semiconductor substrate and the first semiconductor layer.

17. The light emitting device according to claim 16, wherein the first electrode is contacting the junction layer.

18. A light emitting device, comprising:
a light emitting element including:
a semiconductor substrate including a first region of a first conductivity type;
a first semiconductor layer of a second conductivity type disposed on a first surface of the semiconductor substrate;
a second semiconductor layer of the first conductivity type disposed on the first semiconductor layer;
a light emitting layer disposed between the first semiconductor layer and the second semiconductor layer;
a first electrode electrically connected to the first semiconductor layer;
a second electrode electrically connected to the second semiconductor layer;
a third electrode disposed on a second surface of the semiconductor substrate that is opposite the first surface;
a region of the second conductivity type between the first region and the third electrode;
a lead frame to which the light emitting element is mounted; and
a resin disposed so as to cover the light emitting element.
